(19) United States
(12) Patent Application Publication
(10) Pub. No.: US 2004/0027877 A1
(43) Pub. Date: Feb. 12, 2004

(54) Method for setting the threshold voltage of a field-effect transistor, field-effect transistor and integrated circuit

(76) Inventors: Dietmar Kotz, Moosburg (AT); Rudolf Zelsacher, Klagenfurt (AT)

Correspondence Address: LERNER AND GREENBERG, P.A., POST OFFICE BOX 2480, HOLLYWOOD, FL, 33022-2480, US

(21) Appl. No.: 10/455,682

(22) Filed: Jun. 5, 2003

(30) Foreign Application Priority Data
Jun. 5, 2002 (DE) 102 24 956.3

(51) Int. Cl. G11C 29/00

(52) U.S. Cl. 365/200

(57) ABSTRACT

In a field-effect transistor, an electric field is produced above the gate dielectric, and generates a tunneling current through the gate dielectric. The tunneling current, lying below the breakdown charge of the gate dielectric, leads to the formation of stationary charges in the gate dielectric, which can alter the threshold voltage of the field-effect transistor. Thus, customary field-effect transistors can be programmed and, in particular, used for storing data values.

### BACKGROUND OF THE INVENTION

### Field of the Invention

The invention lies in the field of semiconductor technology and relates to a method for setting the threshold voltage of a field-effect transistor.

In order to construct so-called one-time programmable (OTP) memory modules, use is made of components which can only be programmed once but whose programming is permanent, i.e. nonvolatile. The permanent storage is achieved through an irreversible change of the individual components used for storage. This is desirable e.g. where the intention is to prevent a subsequent manipulation.

One possibility for permanent, nonvolatile storage may be seen in the use of so-called fuses (electrical protection devices). The term fuse (interruption) or antifuse (production of a conducting connection) is used depending on whether they can be used to interrupt a current flow or produce a conducting connection. The additional area requirement is disadvantageous in both cases. Moreover, additional fabrication steps are needed. In the case of antifuses, an electrical breakdown is produced with the aid of an electric field. In this case, a Fowler-Nordheim tunneling current is generated which has a sufficient intensity to destroy the insulating dielectric. A conductive connection is produced as a result. In the case of fuses, by contrast, an existing conducting path is generally melted thermally. This can be done either by a momentary current flow or by a focused laser beam. In the case of the latter, the fuse must be optically accessible.

Finally, permanent storage can also be achieved by using so-called zapping diodes. However, the latter have a high area requirement and are laborious in their actions.

A further possibility for nonvolatile storage consists in the use of field-effect transistors having an additional floating gate. The floating gate is disposed between the gate dielectric and the driven gate electrode and is insulated from the latter. Charge that leads to alteration of the threshold voltage Uₜₕ of the filed-effect transistor is stored in the floating gate. The altered threshold voltage can be interpreted as a data value. Two mechanisms are suitable, in principle, for applying charges to the floating gate, and these mechanisms will be outlined briefly below.

First, it is possible to excite electrons to effect tunneling through a special tunnel dielectric present besides the gate dielectric. To that end, a sufficiently high voltage is applied between the gate electrode and the source and/or drain region, which voltage also raises the potential of the floating gate at the same time. In this case, the voltage must be high enough to produce a sufficiently high field strength above the gate dielectric in order that electrons can tunnel through the tunnel dielectric e.g. from the drain region to the floating gate. Accordingly, through the tunneling current, electrons flow to or from the floating gate. The term Nordheim-Fowler tunneling is also used for this type of charge transport.

Another possibility for applying charges to the floating gate is to use so-called hot electrons. To that end, electrons are greatly accelerated by a correspondingly high voltage between the source and drain region and, in the process, may also overcome the potential barrier of the gate dielectric. More detailed indications with regard to these mechanisms can be gathered from the reference by D. Wiedmann et al., titled “Technologie integrierter Schaltungen” [“Technology of Integrated Circuits”], Springer-Verlag, 2nd Edition, p. 293 et seq., and U.S. Pat. No. 5,553,016.

Floating gate transistors have the disadvantage of increased manufacturing outlay compared with “normal” transistors.

U.S. Pat. No. 5,835,402 discloses an integrated circuit in which a field-effect transistor is used as a storage capacitor. Source and drain regions are connected to one another and form one capacitor plate. The other capacitor plate is formed by the gate electrode. A data value is stored by the gate dielectric being destroyed by the production of a breakdown current. The two capacitor plates, i.e. the gate electrode and the source and drain region, are thereby conductively connected to one another. A transistor function of this component is thus precluded.

### SUMMARY OF THE INVENTION

It is accordingly an object of the invention to provide a method for setting the threshold voltage of a field-effect transistor, a field-effect transistor and an integrated circuit that overcome the above-mentioned disadvantages of the prior art methods and devices of this general type, in which the invention specifies a comparatively simple possibility for storing a data value.

With the foregoing and other objects in view there is provided, in accordance with the invention, a method for altering a threshold voltage. The method includes providing at least one field-effect transistor having a source region, a drain region, a channel region extending between the source region and the drain region, a gate electrode with an electrical connector, and only a gate dielectric disposed between the gate electrode and the channel region. A flow of a quantity of charge is provided through the gate dielectric for altering the threshold voltage of the field-effect transistor.

The aim is for the threshold voltage of the field-effect transistor to be altered and set in a targeted manner through electrical modification of the gate dielectric. In this case, the electrical modification is brought about by a flow of a prescribed quantity of charge through the gate dielectric. Without intending to be restrictive, the modification of the gate dielectric can be explained as follows. A voltage applied to the gate electrode produces an electric field permeating the gate dielectric. Either the substrate, in which the channel region is situated, and/or the source and/or drain region serves as a counterelectrode. The voltage is thus essentially dropped across the gate dielectric. On account of the electric field produced as a result, a tunneling current (charge flow) is generated which produces stationary charges in the gate dielectric. By way of example, electrons which tunnel through the gate dielectric can drive out electrons bound in the gate dielectric which then migrate, on account of the prevailing electric field, from the gate dielectric either in the direction of the gate electrode or in the direction of the channel region, depending on the direction of the applied electric field. Positively charged atomic residues remain. In this case, the magnitude of the tunneling current is set in such a way that a dielectric breakdown can be reliably avoided, i.e. the quantity of charge remains below the quantity of charge that is critical for a breakdown. Accordingly, the gate dielectric is not destroyed. In particular, it remains electrically insulating inspite of the charges produced. The magnitude of the quantity of charge flowing through the gate dielectric can be varied within wide ranges, as required.

Bound positive charges are preferably produced in this case. The change in the threshold voltage ΔUₜₕ=Uₜₕ (after modification)−Uₜₕ (before modification) is therefore negative in this case. By way of example, the threshold voltage of a “normally off” NMOS field-effect transistor can thus be reduced by the method according to the invention to an extent such that the transistor is already open without voltage applied to the gate electrode. The threshold voltage is proportional to the quantity of stationary charges produced, and the following holds true:

Uₜₕ˜−Q_{f}/Cᵢ

where Uₜₕ is the threshold voltage, Q_{f} is quantity of stationary charge, and Cᵢ≡εₒε_{dielectric}/d is the capacitance per unit area with εₒ as an electric constant, ε_{dielectric} as a dielectric constant of the gate dielectric and d as thickness of the gate dielectric (see the reference by S. M. Sze, Physics of Semiconductor Devices, Wiley Inter-Science, 2nd Edition, pp. 438-442). Accordingly, the threshold voltage can be varied by way of the quantity of stationary charges and the latter in turn by way of the quantity of charge flowing. The quantity of charge, which results from current intensity times time, can be determined relatively simply. In this case, the current intensity depends, in particular, on the strength of the electric field built up. The time duration can be set by the duration of the applied voltage.

The current tunneling through the gate dielectric may be referred to as a Fowler-Nordheim tunneling current and thus corresponds to the current that occurs when writing to and erasing a floating gate transistor, with the difference that, in the method according to the invention, charges which are fixed in the gate dielectric are produced, this not being effected in a floating gate transistor since there the tunneling current does not flow through the gate dielectric, but rather through the tunnel dielectric, which does not determine the threshold voltage of the transistor. Moreover, in the floating gate transistor, the threshold voltage is determined by the charge accumulated in the floating gate. By contrast, the alteration of the threshold voltage is based, according to the invention, essentially only on the electrical modification of the gate dielectric.

In contrast to the floating gate cell, in which the threshold voltage is set by storing a charge on the floating gate, according to the invention the threshold voltage is set through electrical modification of the gate dielectric. Therefore, it is possible to dispense with a floating gate between the gate dielectric and the gate electrode. The gate electrode provided with an electrical connection is therefore disposed directly on the gate dielectric seated on the substrate. Via its electrical connection, a voltage can be directly applied to it, so that the gate electrode serves both for the setting of the threshold voltage and for the actual driving of the field-effect transistor.

The change in the threshold voltage that is brought about by the charge flow is partly reversible. The temperature plays a considerable part in this case. The higher the temperature at which the field-effect transistor is operated after the change in the threshold voltage, the faster the threshold voltage strives toward its original value again, i.e. the changed threshold voltage can be taken back again through additional thermal treatment. Therefore, if the threshold voltage is to be maintained permanently, or at least for relatively long periods of time, an ambient temperature that is as low as possible must be taken into consideration.

In the case of silicon oxide as material for the gate dielectric, the critical quantity of charge at which an electrical breakdown takes place (also referred to as breakdown charge Q_{crit}) is dependent on the current density. Thus, in the case of silicon oxide, for example, the breakdown charge decreases with increased current density. More detailed information on this problem area can be gathered from the reference by D. Wiedmann et al., titled “Technologie integrierter Schaltungen”, Springer-Verlag, 2nd Edition, p. 59 et seq. This fact should be taken into account, therefore, when generating the charge flow through the gate dielectric.

A programming charge of the order of magnitude of a few percent of the critical quantity of charge Q_{crit} of the respective gate dielectric suffices for setting or changing the threshold voltage. Less than 2% Q_{crit}, in particular about 0.5% Q_{crit}, suffices, by way of example. A degradation of the gate dielectric is minimized by virtue of this small programming charge in comparison with the critical quantity of charge.

Preferably, the field-effect transistor is programmed by the change in the threshold voltage, i.e. the threshold voltage is set for the desired purpose. In particular, a data value can be stored by changing the threshold voltage. The shift in the threshold voltage then serves to distinguish the data values. In the simplest case, the field-effect transistor is assigned two data values. By way of example, a field-effect transistor without a changed threshold voltage represents a logic zero, while a field-effect transistor with a changed threshold voltage represents a logic one. The minimum magnitude of the change in the threshold voltage can be chosen arbitrarily, in principle. In order to be able to reliably ensure discrimination between field-effect transistors with and without a changed threshold voltage, however, a minimum change in the threshold voltage should be chosen. 0.3 V, for example, represents such a change. Therefore, it is preferred for one field-effect transistor to have a threshold voltage at least 0.3 V higher or lower than another field-effect transistor.

A major advantage of the method according to the invention is that the threshold voltage can be altered relatively simply. In particular, the threshold voltage of a standard field-effect transistor, e.g. a MIS field-effect transistor, in particular a MOS or CMOS field-effect transistor, can thus be altered arbitrarily in a simple manner after the completion of the transistor. For this reason, nonvolatile memories can also be constructed even with individual MIS or MOS field-effect transistors, the information to be stored being written in through corresponding programming after the completion of the memory. The programming, independent of production, can be affected at arbitrary times and thus also meet customer-specific requirements. Moreover, no additional process steps are required during production. In particular, all the field-effect transistors can be fabricated in common method steps, irrespective of whether they are subsequently provided as memory transistor or as e.g. switching transistor. It is therefore possible to use any customary very large scale integrated (VLSI) circuit fabrication process in which MIS or MOS field-effect transistors are fabricated, and to use the MOS field-effect transistors that are fabricated in this case as one-time programmable (OTP) elements. To put it another way, OTP elements can be integrated in any integrated circuit having MIS or MOS field-effect transistors, without changing the fabrication process.

Preferably, OTP elements can thus be formed from field-effect transistors, in particular MIS or MOS field-effect transistors. In this case, a memory cell, i.e. the smallest data storage unit, contains only a single field-effect transistor. The space taken up per data value is significantly minimized as a result. The field-effect transistors used for data storage manage without an additional floating gate in this case.

Preferably, at least two, three or more field-effect transistors are provided, the threshold voltage of the individual field-effect transistors being able to be altered independently of one another. Thus, depending on the number of field-effect transistors used, it is possible to store more than just two binary data values.

A multiplicity of field-effect transistors may preferably also be provided in the form of a memory matrix, the threshold voltage of individual field-effect transistors being altered according to the invention for the purpose of storing data values. The memory matrix is preferably a one-time programmable memory matrix.

The method according to the invention can be utilized in diverse ways. By way of example, it can also be used to trim component properties such as e.g. the resistance value of a resistance that is subjected to uncontrollable production fluctuations. In this case, a resistance is formed for example by the total resistance of a resistance network. The total resistance of the resistance network can be established by selective activation of individual resistances of the resistance network. The individual resistances are accordingly added thereto or subtracted.

Another possibility is to store batch numbers, wafer numbers and the position of individual chips on a wafer by corresponding programming of field-effect transistors. This information can subsequently be easily read out electronically. As a result, it is possible to track the individual chips, but also the wafers and the batches in subsequent method steps or even after the completion of the individual chips in order, in the case of subsequent failures, to allow conclusions to be drawn about the production.

Furthermore, the method according to the invention can be used in the activation of dynamic or static memory cells. The programming of a field-effect transistor according to the invention makes it possible, in the event of the failure of memory cells, to activate redundant memory cells, which then replace the defective memory cells.

Another use relates to the storage of arbitrary information in a chip, e.g. an addressing or accident data.

Finally, smart cards can be programmed in a simple manner.

Accordingly, the invention is also generally directed at a method for the, in particular permanent, storage of at least one data value in a field-effect transistor having a source region, a drain region, a channel region extending between the source and drain region, and a gate electrode with electrical connection. Only a gate dielectric is present between the gate electrode and the channel region and the storage being affected by the threshold voltage of the field-effect transistor being changed. In this case, the change is achieved through preferably electrical modification of the gate dielectric. Preferably, a flow of a prescribed quantity of charge through the gate dielectric from or to the gate electrode is produced by applying a voltage to the gate electrode, so that the threshold voltage of the field-effect transistor is altered. In this case, it is possible to produce charges which are fixed in the gate dielectric and which lead to the alteration of the threshold voltage.

The invention furthermore relates to a field-effect transistor whose threshold voltage is altered by the method according to the invention. In particular, such a field-effect transistor forms a nonvolatile memory cell. Preferably, the memory cell contains only one field-effect transistor, e.g. a MOS field-effect transistor, which need not have a floating gate. The field-effect transistor according to the invention is preferably a 1-bit OTP element, which is to say that a 1-bit data value can be stored in the field-effect transistor. The memory cell can therefore be restricted to only a single field-effect transistor. It is particularly small as a result.

The invention furthermore relates to an integrated circuit having at least one field-effect transistor having a source and a drain region, a channel region extending between the source and drain region and a gate electrode with electrical connection, only a gate dielectric being present between the gate electrode and the channel region. The integrated circuit according to the invention is distinguished by the fact that the at least one field-effect transistor can be programmed by altering its threshold voltage.

Preferably, the alteration of the threshold voltage of the field-effect transistor is essentially brought about merely by charges that are fixed in the gate dielectric. The charges may be formed e.g. by the method described further above.

It is furthermore preferred if the integrated circuit contains a memory matrix with a multiplicity of memory cells, each memory cell containing precisely one field-effect transistor. Integrated circuits of this type have a minimal area per memory cell, which is determined only by the area required for the field-effect transistor. The field-effect transistors may be MOS field-effect transistors which are used e.g. as switches in logic circuits or as selection transistors in dynamic memories.

The integrated circuit is preferably a one-time programmable memory matrix, i.e. the stored information is nonvolatile.

Furthermore, it is preferred if the integrated circuit is a dynamic or static semiconductor memory having a multiplicity of dynamic or static memory cells, respectively, dynamic or static memory cells being able to be activated by the programming of the at least one field-effect transistor.

It is likewise preferred for the integrated circuit to have a programmable transistor array (field programmable gate array). As a result, logic applications can be programmed in a simple manner, the advantage residing in particular in the fact that the same type of transistor can be used both for the logic transistors and for the programmable transistors. The fabrication is simplified significantly as a result.

The field-effect transistor is preferably a MOS field-effect transistor. The gate dielectric preferably contains silicon oxide. Other likewise preferred materials are oxynitrides and/or other insulators.

Furthermore, the invention relates to a smart card having an integrated circuit, which has at least one field-effect transistor having a source region, a drain region, a channel region extending between the source and drain region and a gate electrode with electrical connection, only a gate dielectric being present between the gate electrode and the channel region and the at least one field-effect transistor being programmed by its threshold voltage being altered.

Other features which are considered as characteristic for the invention are set forth in the appended claims.

Although the invention is illustrated and described herein as embodied in a method for setting the threshold voltage of a field-effect transistor, a field-effect transistor and an integrated circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A and 1B are diagrammatic, sectional views of the basic construction of NMOS and PMOS field-effect transistors according to the invention;

FIGS. 2A and 2B are plan views of a memory;

FIG. 3 is an illustration of a smart card;

FIGS. 4A and 4B are graphs showing a characteristic curve of NMOS field-effect transistors before and after the method according to the invention is carried out;

FIGS. 5A and 5B are graphs showing the characteristic curve of PMOS field-effect transistors before and after the method according to the invention is carried out;

FIGS. 6 and 7 are graphs showing a change in the threshold voltage of NMOS and PMOS field-effect transistors as a function of time; and

FIG. 8 is a graph showing the extrapolation of the change in the threshold voltage.

### DESCRIPTION OF THE PREFERRED EMBODIMENTS

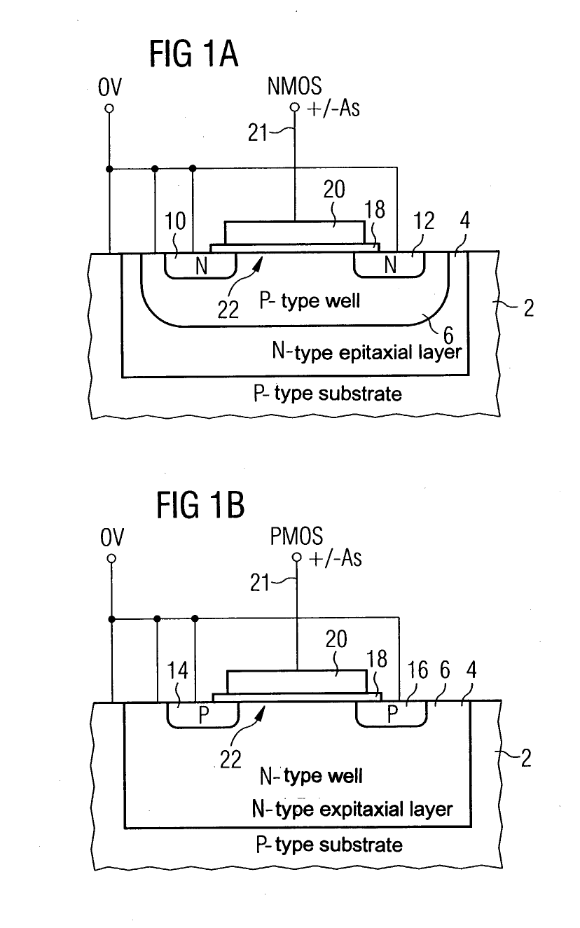

Referring now to the figures of the drawing in detail and first, particularly, to FIGS. 1A and 1B thereof, there is shown the construction of an NMOS and a PMOS field-effect transistor (NMOS, PMOS). Both the NMOS and the PMOS field-effect transistor (NMOS, PMOS) are integrated in a p-type substrate 2, in which an n-conducting region 4 produced epitaxially is provided. The region 4 might also have been produced in a different way. For the NMOS field-effect transistor (NMOS), a p-conducting well 6 is introduced within the n-conducting region 4. By contrast, the PMOS field-effect transistor (PMOS) requires an n-conducting well, which is formed by the n-conducting region in this case (FIG. 1B). The n-conducting source and drain regions 10 and 12 of the NMOS field-effect transistor (NMOS) are introduced into the p-conducting well 6. By contrast, the PMOS field-effect transistor (PMOS) has p-conducting source and drain regions 14 and 16 within the n-conducting region 4 (FIG. 1B). The source and drain regions 10, 12, 14, 16 are in each case provided with connections. Gate dielectrics 18, which cover channel regions 22 lying between the source and drain regions 10, 12, 14, 16, are seated on the substrate 2. Gate electrodes 20, which are each provided with an electrical connection 21, are situated on the gate dielectric 22. Both NMOS and PMOS field-effect transistors may be integrated in a common substrate and be part of an integrated circuit.

In order to alter the threshold voltage, in the NMOS field-effect transistor (NMOS), the source and drain regions 10, 12 and also the p-type well 6 and the substrate 2 are clamped to e.g. 0 V, whereas a negative voltage is applied to the gate electrode 20, with the consequence that a tunneling current is produced through the gate dielectric 18. In the PMOS field-effect transistor, by contrast, a positive voltage is applied to the gate electrode 20 under otherwise identical conditions. However, positive and negative voltages are possible both for NMOS and PMOS field-effect transistors.

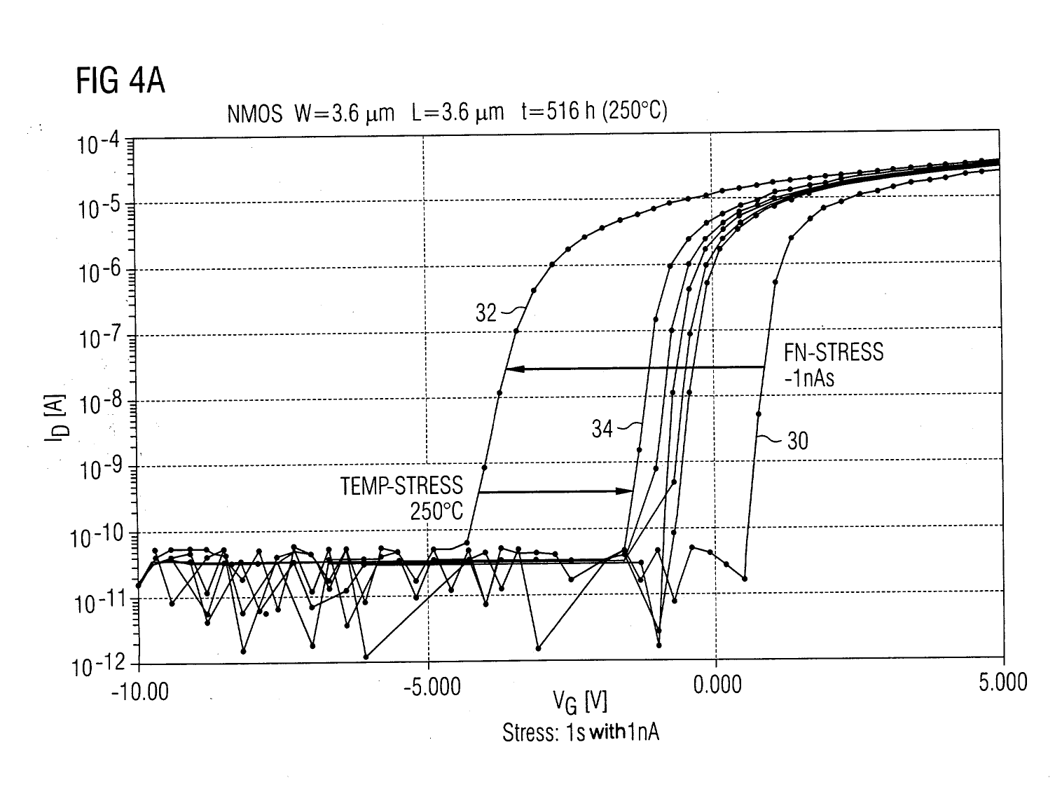

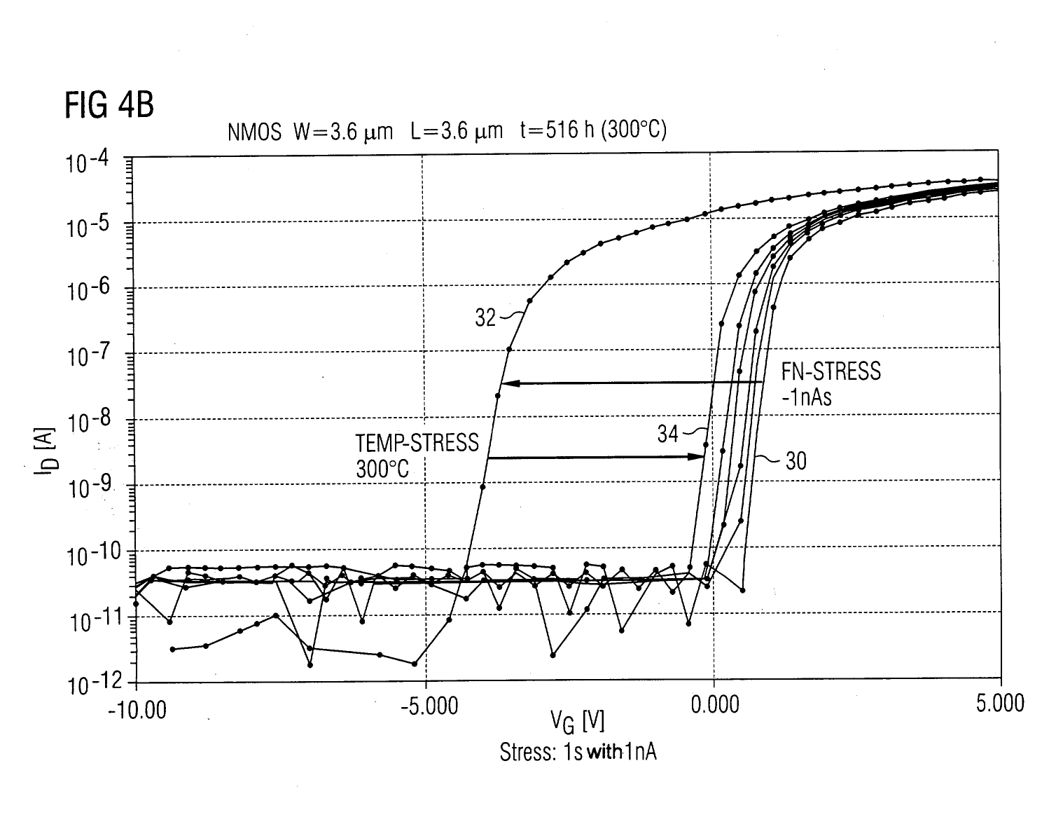

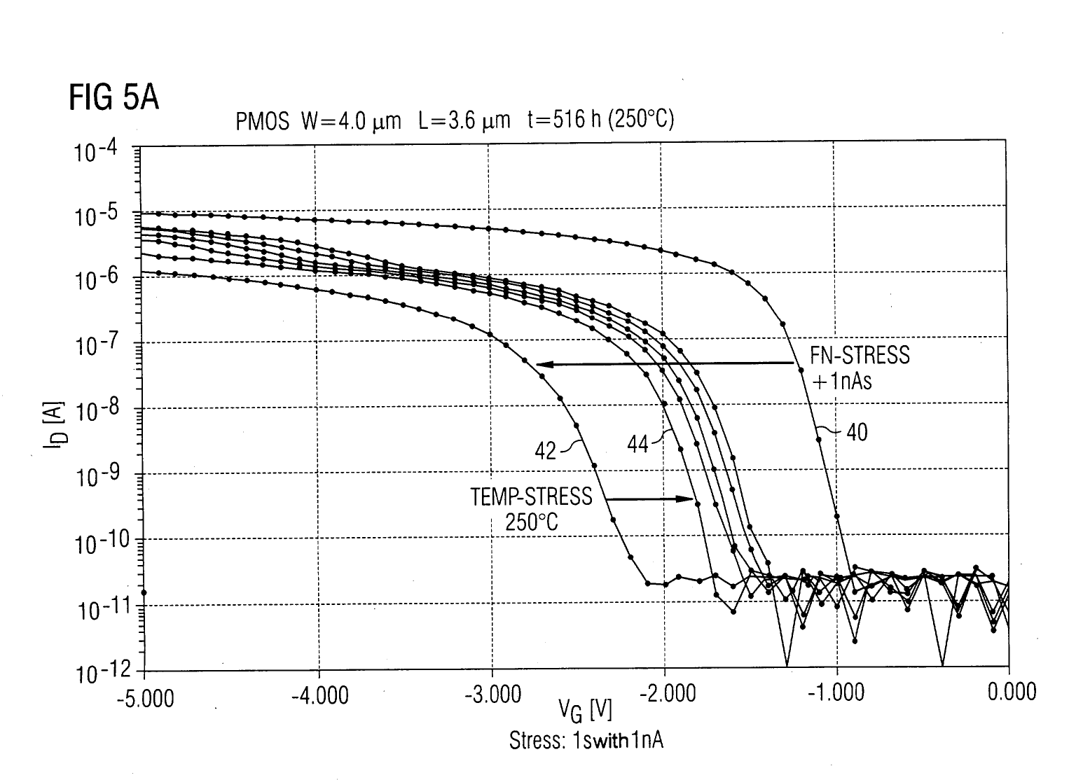

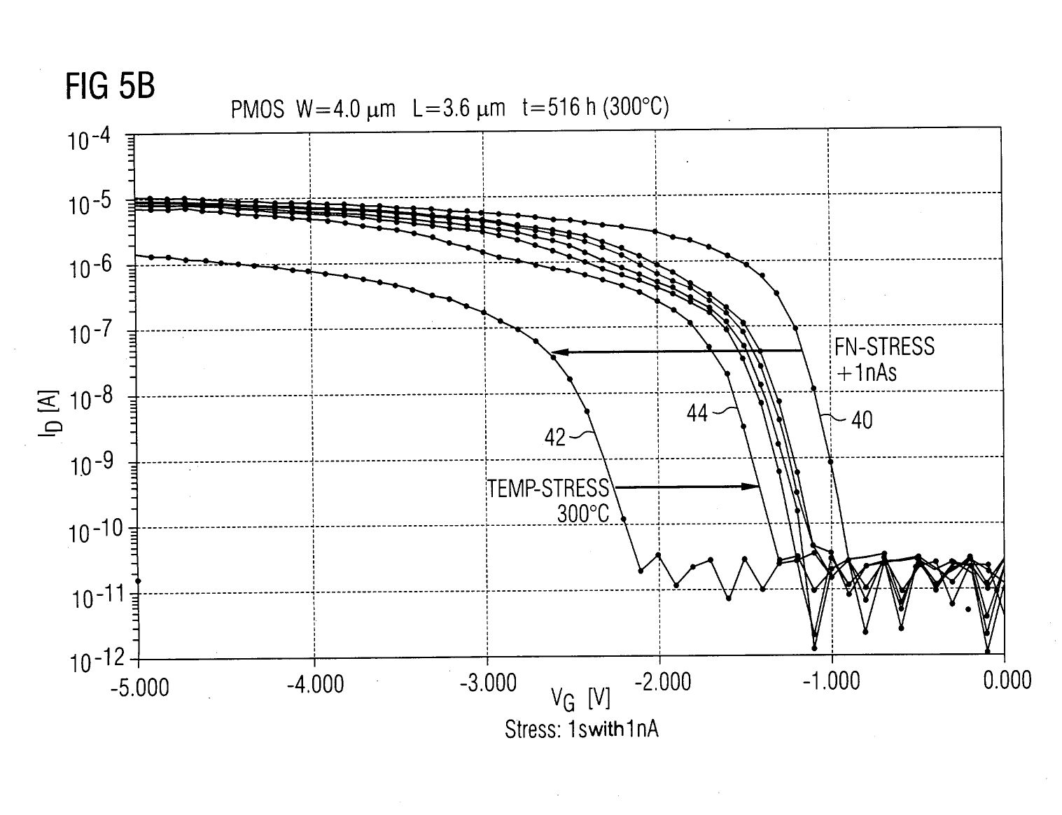

FIGS. 4A to 5B show the change in the characteristic curve of the NMOS and of the PMOS field-effect transistor after the through-flow of a quantity of charge of 1 nAs. In FIG. 4A, the characteristic curve before the through-flow of the quantity of charge is designated by 30. After the method has been carried out, i.e. in this concrete example after the through-flow of a quantity of charge of 1 nAs, the characteristic curve is shifted significantly in the direction of negative values. V_{G} designates a voltage applied to the gate electrode and I_{D} designates the current measured on the drain side. The characteristic curve determined directly after the application of the charge flow specified is designated by 32. The characteristic curve shifts toward positive values again depending on the temperature, i.e. it approximates to its original position again. 34 designates characteristic curves measured after the storage of the NMOS field-effect transistor for t=516 h at a temperature of 250° C. The return to the original characteristic curve is more pronounced at higher temperatures. FIG. 4B shows the same facts as in FIG. 4A, with the difference that here the NMOS field-effect transistor was stored at 300° C. for 516 h. The original characteristic curve is almost reached again. In both cases, the NMOS field-effect transistor had a channel width W of 3.6 μm and a channel length L of 3.6 μm. The thickness of the gate dielectric was 55 nm. Silicon oxide was used as a material.

The same investigations were also carried out with a PMOS field-effect transistor. The latter had, in contrast to the NMOS field-effect transistor, a channel width W of 4.0 μm and a channel length of 3.6 μm with a gate dielectric thickness of 55 nm. Silicon oxide was likewise used as a material. The characteristic curve is likewise shifted in the direction of negative values. In terms of magnitude, the quantity of charge that flowed through the gate dielectric corresponds to that in the case of the NMOS in FIGS. 4A and 4B, but with an opposite sign. 40 designates the characteristic curve before the through-flow of the quantity of charge, 42 designates the characteristic curve immediately afterward, and 44 denotes the characteristic curves after 516 h. FIGS. 5A and 5B differ only in the magnitude of the temperature at which the PMOS field-effect transistors were stored after the method according to the invention had been carried out.

As a result of the applied charge flow, the gate dielectric was stressed by a Fowler-Nordheim tunneling current with the consequence of electrically active positive charges being generated in the gate dielectric, the charges bringing about the shift in the threshold voltage toward negative values.

In the case of the gate dielectric made of a silicon oxide layer having a thickness of 55 nm that was specifically examined in this exemplary embodiment, the critical charge (or critical surface charge density Q_{crit}) required for an electrical breakdown is about 2-3 As/cm². For the shift in the threshold voltage, in the NMOS field-effect transistor with a gate dielectric area of 13 μm², with an applied charge flow, a stress surface charge density Qₛₜᵣₑₛₛ of 7.7 mAs/cm² was achieved. In the PMOS field-effect transistor with its gate dielectric area of 14.4 μm², a stress surface charge density Qₛₜᵣₑₛₛ of 7 mAs/cm² was achieved. The stress charge acting on the gate dielectric both of the NMOS field-effect transistor and of the PMOS field-effect transistor is thus about 2 to 3 orders of magnitude less than the critical breakdown charge. Accordingly, an electrical breakdown is precluded.

The alteration of the threshold voltage both of the NMOS field-effect transistor and of the PMOS field-effect transistor took place at a temperature of 25° C. In the case of the NMOS field-effect transistor, at a time of t=0.01 h after the flow of the quantity of charge of 1 nAs, a shift (ΔUₜₕ) in the threshold voltage of up to 5 V was observed, and of up to 2.2 V in the case of the PMOS field-effect transistor.

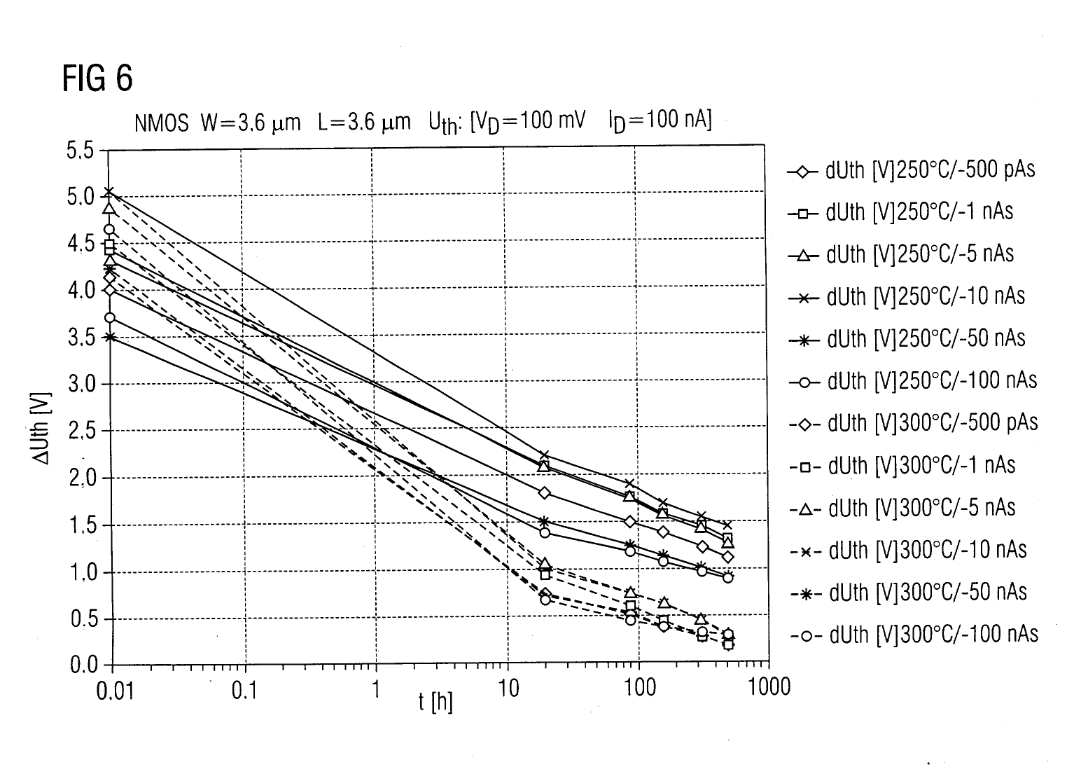

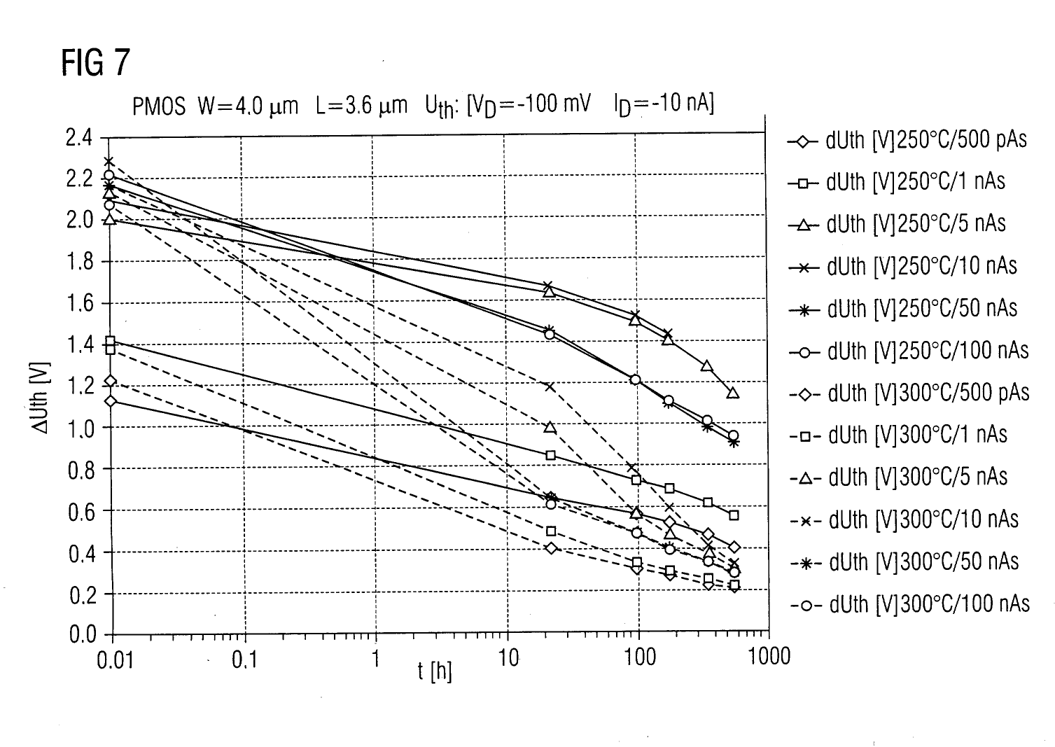

The magnitude of the shift in the threshold voltage as a function of the quantity of charge that flowed through the gate dielectric and of the time duration of the storage at 250 and 300° C. is respectively illustrated for the NMOS field-effect transistor in FIG. 6 and for the PMOS field-effect transistor in FIG. 7. Although the quantity of charge which flowed through the gate dielectric varies in part by several orders of magnitude, the changes in the threshold voltage directly after the application of the method according to the invention lie in the range between 3.5 and 5 V for the NMOS field-effect transistor and in the range between 1.1 and 2.3 V for the PMOS field-effect transistor. In order to determine the threshold voltage, in the PMOS field-effect transistor, a voltage V_{D} of −100 mV was applied between source and drain regions and the voltage applied to the gate electrode was increased until a current I_{D} of −10 nA was measured on the drain side. The NMOS field-effect transistor, by contrast, worked with a voltage between source and drain regions V_{D} of 100 mV, a drain-side current flow I_{D} of 100 nA having been assumed as a criterion for the threshold voltage Uₜₕ of the NMOS field-effect transistor. Despite, in some instances, of the relatively high stress charge of up to 100 nAs, this is still significantly less than the critical charge.

Therefore, a field-effect transistor can be programmed by the method according to the invention. In this case, the programming is affected by the permanent alteration of the threshold voltage. Consequently, “normal” field-effect transistors can be used e.g. as OTP elements. The alteration of the threshold voltage can be interpreted as a data value.

It should be taken into consideration that the alteration of the threshold voltage by the tunneling current (stress charge) may be partially reversible. The temperature plays a significant part in this case. Accordingly, at a correspondingly high temperature, the threshold voltage can also be taken back to its original value again, i.e. the stored value is practically erased. This should be taken into account for practical use. Reversibility is insignificant, by contrast, in those cases in which the programming is required only for finite periods of time.

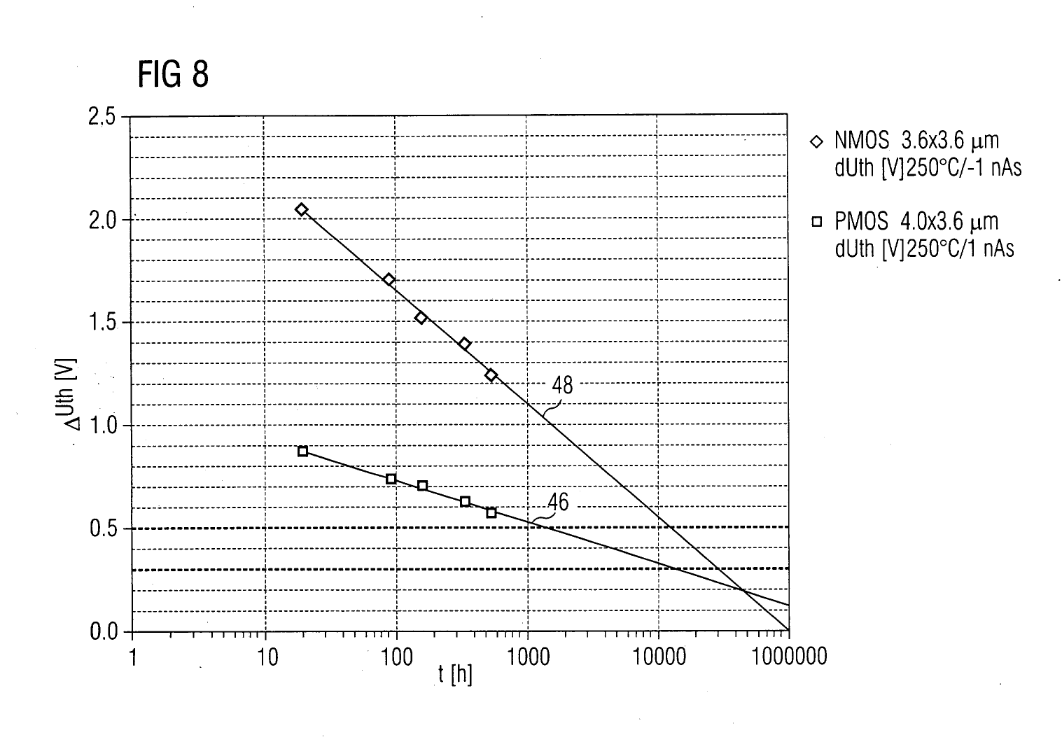

It can clearly be recognized that the difference ΔUₜₕ between the original threshold voltage and the threshold voltage obtained after electrical modification decreases faster at higher temperatures. In this case, the decline of ΔUₜₕ is a logarithmic function of time t. This is shown e.g. in FIG. 8, which illustrates by way of example the extrapolation of ΔUₜₕ to longer times with storage at 205° C. If e.g. a shift in the threshold voltage of 0.5 V is regarded as sufficient for a discrimination (in the case of programming), a data value can be stored for about 1000 hours in a PMOS field-effect transistor that is programmed with 1 nAs and is stored or operated at 250° C. The shift in the threshold voltage of the PMOS field-effect transistor is designated by 46. An NMOS field-effect transistor can store a data value even for more than 10,000 hours under otherwise identical conditions. Its threshold voltage is designated by 48. If a difference of 0.3 V suffices for distinguishing between changed and non-changed threshold voltage, data values can be stored for significantly longer than 10,000 hours in both field-effect transistors, and for even more than 30,000 hours in the NMOS. Since the temperature at which a MOS field-effect transistor is operated or stored is significantly less than 250° C., from a practical standpoint it is even possible to achieve considerably longer periods of time.

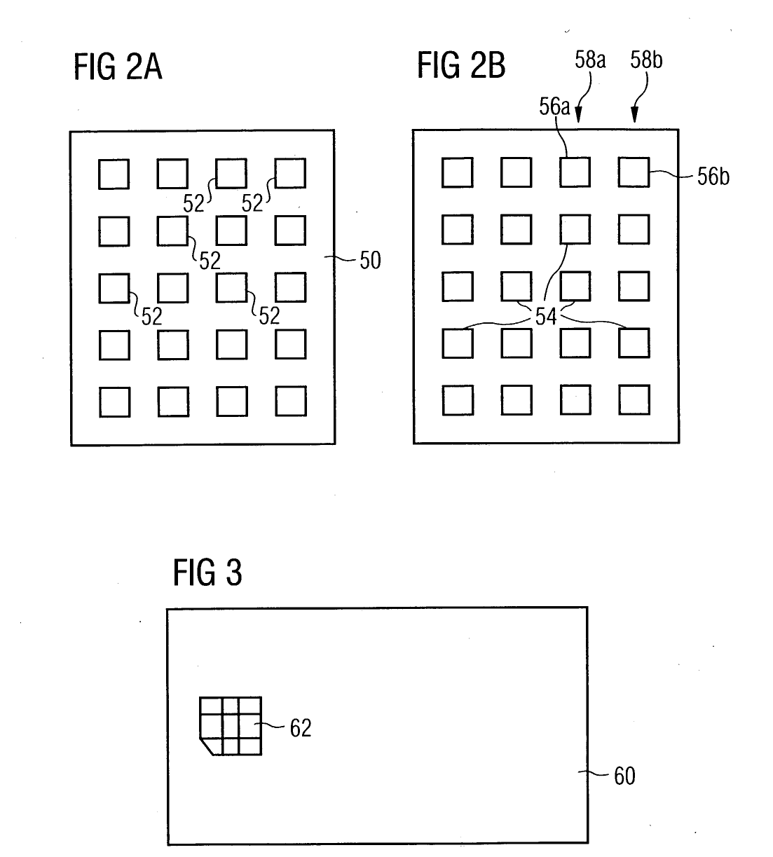

FIG. 2A diagrammatically illustrates a memory cell matrix 50 having a multiplicity of memory cells 52. Each memory cell 52 contains only one MOS field-effect transistor, whose threshold voltage is programmed by electrical modification of its gate dielectric in accordance with the method described above.

By contrast, FIG. 2B shows a dynamic or static memory 53 having a multiplicity of dynamic or static memory cells 54, respectively. Memory cells 56a and 56b each containing one field-effect transistor serve for activating the memory cells 54 as required. By way of example, the column 58a is activated by the field-effect transistor of the memory cell 56a being programmed by the method described above, while the column 58b is not activated.

FIG. 3 shows a smart card 60 with a chip 62 integrated therein. The chip contains an integrated circuit with at least one MOS field-effect transistor altered in this way.

We claim:

1. A method for altering a threshold voltage, which comprises the steps of:
providing at least one field-effect transistor having a source region, a drain region, a channel region extending between the source region and the drain region, a gate electrode with an electrical connector, and only a gate dielectric disposed between the gate electrode and the channel region; and
producing a flow of a quantity of charge through the gate dielectric for altering the threshold voltage of the field-effect transistor.

2. The method according to claim 1, which further comprises applying a voltage to the gate electrode for bringing about the flow of the quantity of charge.

3. The method according to claim 1, which further comprises using the flow of the quantity of charge to produce charges fixed in the gate dielectric for leading to an alteration of the threshold voltage Uₜₕ.

4. The method according to claim 1, which further comprises determining the quantity of charge by a prescribed current intensity and a prescribed duration.

5. The method according to claim 1, which further comprises setting the quantity of charge to lie below a quantity of charge leading to a destruction of the gate dielectric, thereby precluding an electrical breakdown of the gate dielectric.

6. The method according to claim 1, which further comprises programming the field-effect transistor through an alteration of the threshold voltage.

7. The method according to claim 1, which further comprises storing a data value in the field-effect transistor through an alteration of the threshold voltage.

8. The method according to claim 7, which further comprises:
providing a multiplicity of field-effect transistors in a form of a memory matrix; and
altering the threshold voltage of individual field-effect transistors for storing data values.

9. The method according to claim 8, which further comprises forming the memory matrix to be a one-time programmable memory matrix.

10. The method according to claim 1, which further comprises forming the field-effect transistor as a MIS field-effect transistor.

11. The method according to claim 1, which further comprises forming the gate dielectric from a material selected from the group consisting of silicon oxide and oxynitride.

12. A field-effect transistor, comprising:
a substrate;
a source region disposed in said substrate;
a drain region disposed in said substrate;
a channel region extending between said source region and said drain region;
a gate electrode with an electrical connector disposed above said channel region; and
only a gate dielectric disposed between said gate electrode and said channel region, and a flow of a quantity of charge through said gate dielectric altering a threshold voltage of the field-effect transistor.

13. The field-effect transistor according to claim 12, wherein the field-effect transistor forms a nonvolatile memory cell.

14. An integrated circuit, comprising:
at least one field-effect transistor having a threshold voltage, a source region, a drain region, a channel region extending between said source region and said drain region, a gate electrode with and an electrical connection, and only a gate dielectric disposed between said gate electrode and said channel region, said field-effect transistor being programmed by altering said threshold voltage.

15. The integrated circuit according to claim 14, wherein an alteration of said threshold voltage of said field-effect transistor is brought about by charges being fixed in said gate dielectric.

16. The integrated circuit according to claim 14, further comprising a memory matrix having a multiplicity of memory cells, and each of said memory cells having one said field-effect transistor.

17. The integrated circuit according to claim 14, wherein the integrated circuit is a one-time programmable memory matrix.

18. The integrated circuit according to claim 14,
wherein said field effect transistor is one of a plurality of field effect transistors; and
further comprising a dynamic semiconductor memory having a multiplicity of dynamic memory cells activated by programming said field effect transistors.

19. The integrated circuit according to claim 14, further comprising a programmable transistor array.

20. The integrated circuit according to claim 14, wherein said field-effect transistor is a MIS field-effect transistor.

21. The integrated circuit according to claim 14, wherein said gate dielectric is formed of a material selected from the group consisting of silicon oxide and oxynitride.

22. The integrated circuit according to claim 14,
wherein said field effect transistor is one of a plurality of field effect transistors; and
further comprising a static semiconductor memory having a multiplicity of static memory cells activated by programming said field-effect transistors.

23. A smart card, comprising:
an integrated circuit containing at least one field-effect transistor having a threshold voltage, a source region, a drain region, a channel region extending between said source region and said drain region, a gate electrode with an electrical connection, and only a gate dielectric disposed between said gate electrode and said channel region, said field-effect transistor being programmed by altering said threshold voltage.
